(19) United States
(12) Patent Application Publication
(10) Pub. No.: US 2015/0268270 A1
(43) Pub. Date: Sep. 24, 2015

(54) TESTING DEVICE

(71) Applicants: Fu Tai Hua Industry (Shenzhen) Co., Ltd., Shenzhen (CN); HON HAI PRECISION INDUSTRY CO., LTD., New Taipei (TW)

(72) Inventors: JU-LAN HAO, Shenzhen (CN); WEI-CHIANG LIN, New Taipei (TW)

(21) Appl. No.: 14/498,372

(22) Filed: Sep. 26, 2014

(30) Foreign Application Priority Data
Mar. 21, 2014 (CN) 201410107999X

(51) Int. Cl. G01R 1/04; G01R 31/28

(52) U.S. Cl. CPC G01R 1/0416; G01R 31/2889

(57) ABSTRACT

A testing device for avoiding an electronic device accidently being detached in test, includes a bracket for receiving the electronic device therein, a first latching member attached to a first end of the bracket and configured to slide between a latched position and a released position, and a second latching member attached to a second end opposite the first end of the bracket and configured to slide between a latched position and a released position. The electronic device is located in the bracket, when the first latching member and the second latching member are in their respective latched positions. The electronic device extends beyond the bracket, when the first latching member and the second latching member are in their respective released positions.

### FIELD

The subject matter herein generally relates to a testing device

### BACKGROUND

Electronic products can be detached from testing devices accidently during testing.

### BRIEF DESCRIPTION OF THE DRAWINGS

Implementations of the present technology will now be described, by way of example only, with reference to the attached figures.

FIG. 1 is an exploded, isometric view of an embodiment of a testing device.

FIG. 2 is similar to FIG. 1, but shown from another angle.

FIG. 3 is a partially, enlarged view of FIG. 1.

FIGS. 4 and 5 are assembled views of FIG. 1, but show the testing device in different states.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “outside” refers to a region that is beyond the outermost confines of a physical object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “inside” indicates that at least a portion of a region is partially contained within a boundary formed by the object. The term “comprising” means “including, but not necessarily limited to”; it specifically indicates open-ended inclusion or membership in a so-described combination, group, series and the like.

The present disclosure is described in relation to a testing device.

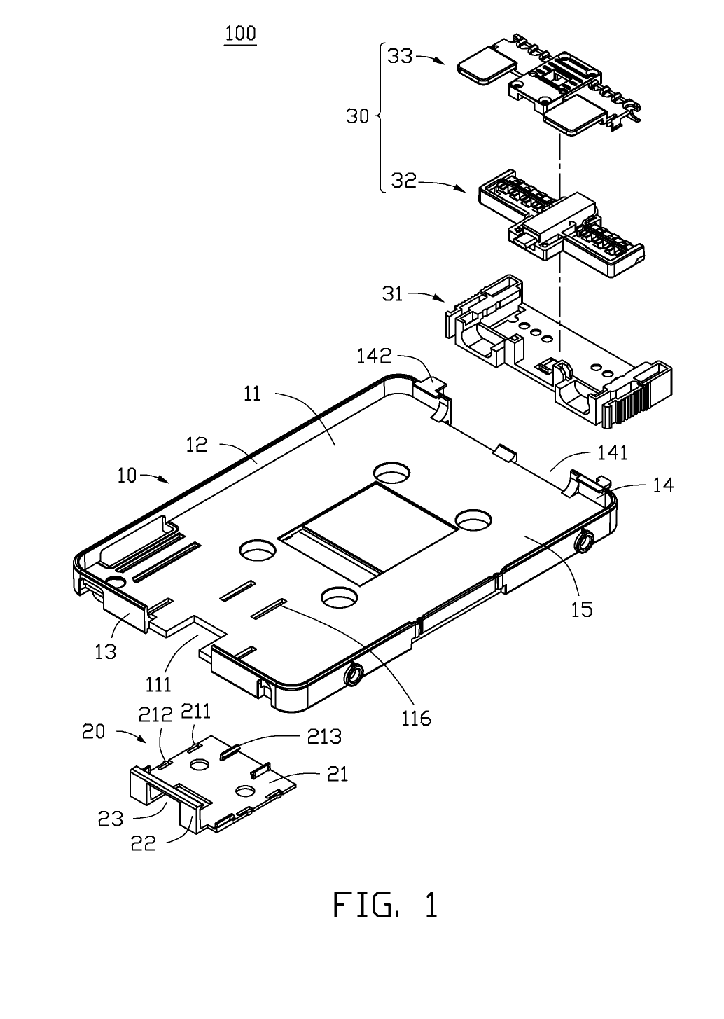

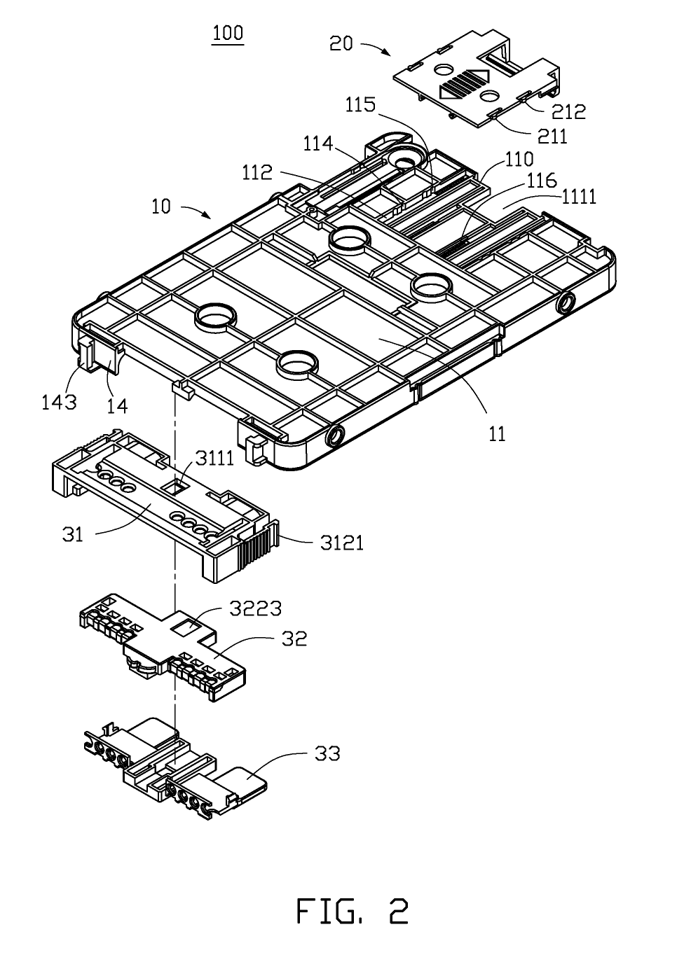

FIGS. 1 and 2 illustrate an embodiment of a testing device 100 for avoiding the detachment of an electronic device during testing. The testing device 100 comprises a bracket 10, a first latching device 20, a mounting tray 31, and a second latching device 30.

The bracket 10 comprises a bottom plate 11, two opposite side plates 12, a front end plate 13, and a rear end plate 14. The bottom plate 11, two opposite side plates 12, the front end plate 13 and the rear end plate 14 cooperatively bound a receiving space 15.

A substantially rectangular recessed portion 110 is defined in a bottom wall of the bottom plate 11 near the front end of the bottom plate 11, and comprises a pair of flanges 112 formed at two opposite sides. A first latching hole 114 and a second latching hole 115 are defined in inside of each flange 112. A notch 111 is defined in a front portion of the recessed portion 110. A pair of parallel sliding slots 116 is defined in a rear portion of the recessed portion 110. A cutout 141 is defined in a middle portion of the rear end plate 14. A pair of latching posts 143 each with a substantially L-shaped cross-section is formed at an outside surface of the rear end plate 14, beside the cutout 141. A supporting plate 142 is perpendicularly formed at a top end of each latching post 143.

The first latching member 20 comprises a sliding plate 21, and a positioning hook 22 perpendicularly formed at a front end of a top wall of the sliding plate 21. A pair of elastic sliding hooks 213 extends perpendicularly from a rear portion of the top wall of the sliding plate 21, facing each other. A first latch 211 and a second latch 212 are formed at each side of the sliding plate 21. An operation notch 23 is defined in the positioning hook 22, extending through a front portion of the sliding plate 21.

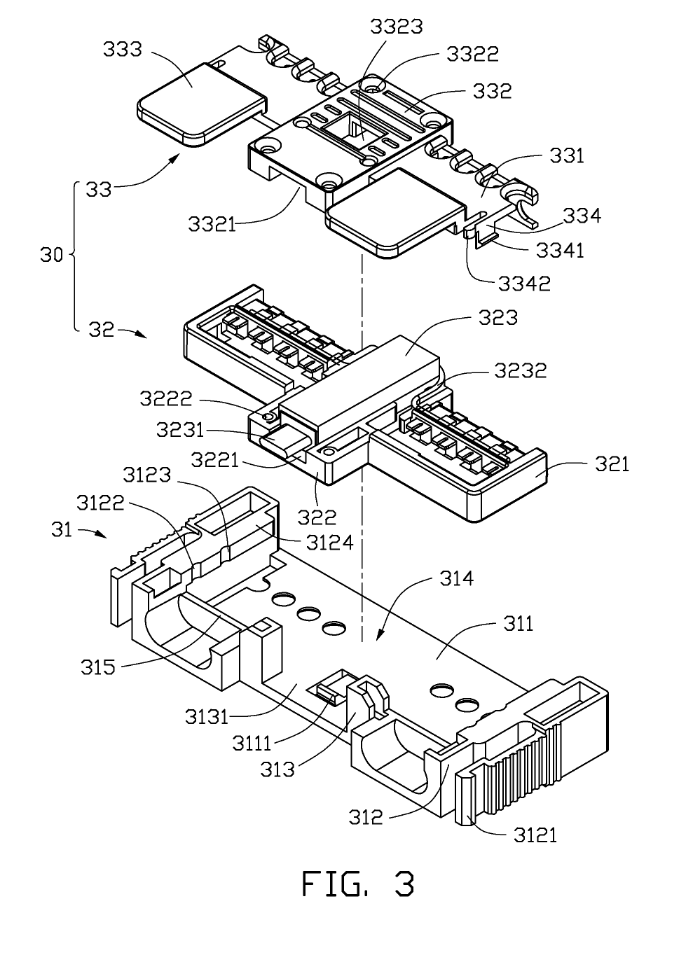

FIG. 3 illustrates the second latching device and the mounting tray. The second latching device 30 is slidably attached to the mounting tray 31 and comprises a positioning member 32, and a sliding member 33.

The mounting tray 31 comprises a bottom wall 311, a pair of side walls 312 extending up from two opposite ends of the bottom wall 311. An elastic locating hook 3111 (shown in FIG. 2) extends upward from a front portion of the bottom wall 311. A pair of spaced guiding posts 313 extends perpendicularly from a front edge of the bottom wall 311, beside the locating hook 3111. A pair of supporting members 315 is formed between the corresponding supporting members 315 and the sidewalls 312. The bottom wall 311, the sidewalls 312, the guiding posts 313 and the supporting members 315 cooperatively define a receiving space 314. A guiding bar 3124 is perpendicularly formed at an inner wall of each sidewall 312. A first latching hole 3122 and a second latching hole 3123 are defined in an inner surface of each guiding bar 3124. A resilient latch 3121 extends forward from an outside surface of each sidewall 312.

The positioning member 32 comprises a substantially rectangular mounting block 322, and a pair of extending blocks 321 perpendicularly formed at two opposite sides of the mounting block 332. A screw hole 3222 is defined in each corner of the mounting block 322. A receiving space 3221 is defined in an upper portion of the mounting block 322 for receiving a connector 323 and a plug 3231 formed at a front end of the connector 323. The connector 323 includes a plurality of cables 3232 formed at a rear end, and clamped by the extending blocks 321. A slot 3223 (shown in FIG. 2) is defined in a bottom of the mounting block 322.

The sliding member 33 comprises a substantially rectangular mounting block 332, and a pair of extending blocks 331 perpendicularly formed at two opposite sides of the mounting block 332. A screw hole 3322 is defined in each corner of the mounting block 332. An operation notch 3323 is defined in a middle portion of the mounting block 332. A receiving space 3321 is defined in a lower portion of the mounting block 332, corresponding to the receiving space 3221 of the mounting member 32. A pair of blocking tabs 333 extends from a front edge of the extending blocks 331, beside the mounting block 332. A resilient extension member 334 extends forward from two opposite ends of each extending block 331. Each extension member 334 includes a latch 3342 formed at a front portion, and a hook 3341 formed at a bottom portion.

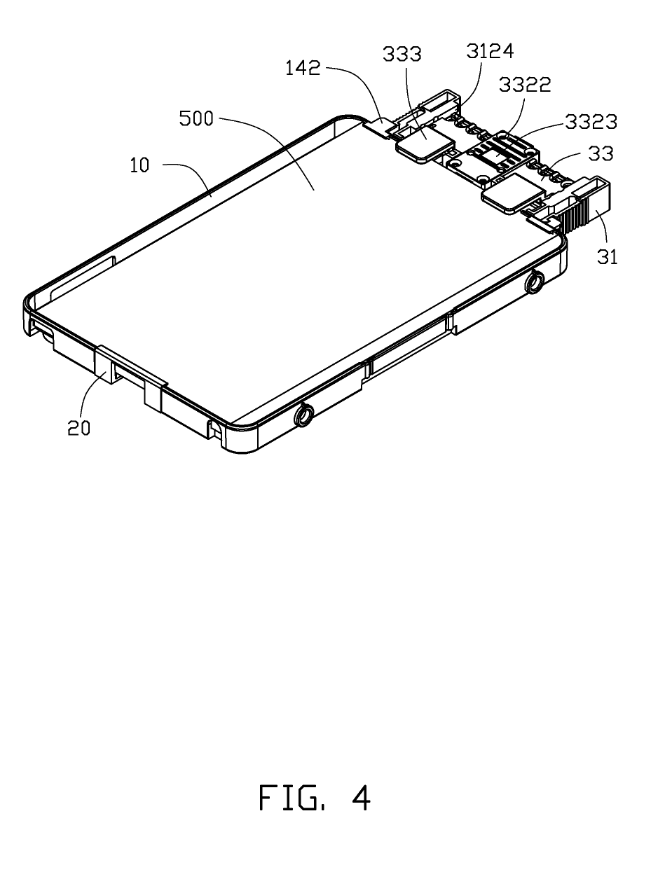

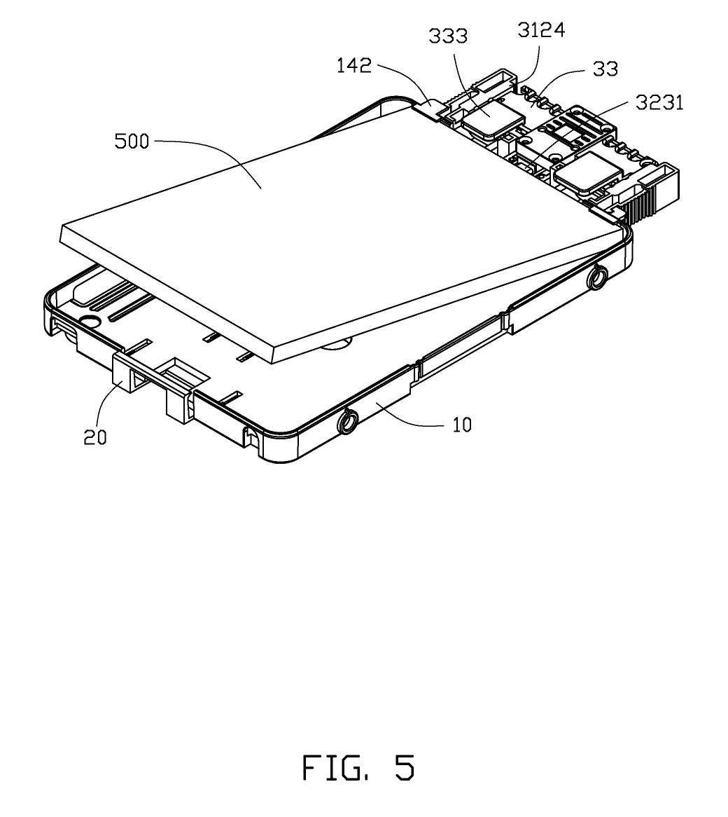

FIGS. 4 and 5 illustrate that, in assembly of the second latching device 30, the connector 323 is received in the receiving space 3321 of sliding member 33 and the receiving space 3221 of the positioning member 32 and four fasteners extend through the screw holes 3322 to engage in screw holes 3222 of positioning member 32, attaching the sliding member 33 to the positioning member 32. The extension members 334 are located at two outer opposite ends of the extending blocks 321. In assembly of the second latch member 30 and the mounting tray 31, the positioning member 32 and the sliding member 33 are slidably received in the receiving space 314 and the mounting block 322 is located between the two guiding posts 313. The hooks 3341 slide along bottoms of the guiding bars 3124. The latches 3342 are engaged in the first latching holes 3122. The latching hook 3111 is slidably engaged in a rear end of the slot 3223. The blocking tabs 333 are slidably supported on the supporting members 315. Thus, the mounting tray 31 and the positioning member 32 can slide relative to the sliding member 33.

In assembly of the mounting tray 31 and the bracket 10, the latches 3121 engage with the latching posts 143. At this time, the second latching member 30 is in a latched position.

In assembly of the first latching member 20 and the bracket 10, the sliding plate 21 is received in the recessed portion 110. The first latches 211 and the second latches 212 engage in the first positioning holes 144 and the second positioning holes 145. The sliding hooks 213 extend through the sliding slots 116, and slide along the top wall of the bottom plate 11. At this time, the first latching member 20 is in a latched position.

To test the electronic device 500, the operation notch 3323 is operated to slide the second latching device 30 away from the bracket 10, until the latches 3342 of the sliding member 33 slide to engage in the second latching holes 3123 and the hook 3111 is detached from the slot 3223. The first latching member 20 is slid away from the bracket 10 by operating the operation notch 23, until the first latches 211 are slid to engage in the second latching holes 115. At this time, the first latching device 20 and the second latching device 30 are in released positions.

The electronic device 500 is able to be placed in the receiving space 15. Then, the first latching member 20 is slid toward the bracket 10, until the first latches 211 are slid to engage in the first latching holes 114, and the second latches 212 are slid to engage in the second latching holes 115. The second latching device 30 is slid toward the bracket 10, until the latches 3342 are slid to engage in the first latching holes 3122, and the latching hook 3111 is engaged in the rear end of the slot 3223. Therefore, the plug 3231 is inserted into the electronic device 500, a front portion of a top of the electronic device 500 is blocked by the blocking tabs 333, and the position hook 22 blocks a rear portion of the top of the electronic device 500.

After testing, the electronic device 500 is detached from the bracket 10. The second latching member 20 is slid away from the bracket 10, until the first latches 211 are slid to engage in the second latching holes 115. The position hook 22 is moved away from the electronic device 500. The second latching member 30 is slid away from the bracket 10, until the latches 3342 engage in the second latching holes 3123, and the latching hook 3111 is engaged in the front end of the slot 3223. Therefore, the plug 3231 is moved away from the electronic device 500, and the blocking tabs 333 are moved away from the electronic device 500. Thus, the electronic device 500 is easily removed from the bracket 10.

The second latch member 30 is slid to latch the electronic device 500 in the bracket 10 during testing. After testing, the first latching member 20 and the second latch member 30 are slid to release the electronic device 500 from the bracket 10, which ensures the electronic device 500 is not removed from the bracket 10 accidently.

The embodiments shown and described above are only examples. Many details are often found in the art such as the other features of a testing device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A testing device for avoiding an electronic device accidently being detached in test, comprising:
a bracket for receiving the electronic device therein;
a first latching member attached to a first end of the bracket and configured to slide between a latched position and a released position; and
a second latching member attached to a second end opposite the first end of the bracket and configured to slide between a latched position and a released position;
wherein, the electronic device is located in the bracket, when the first latching member and the second latching member are in their respective latched positions, the electronic device extends beyond the bracket, when the first latching member and the second latching member are in their respective released positions.

2. The testing device of claim 1, wherein the bracket comprises a bottom plate, a front end plate and a rear end plate formed at two opposite ends of the bottom plate, a mounting tray is attached to the bracket near the rear end plate, the second latch member is slidably attached to the mounting tray, the first latch member is slidably attached to the bracket near the front end plate.

3. The testing device of claim 2, wherein the first latching member comprises a positioning hook perpendicularly for blocking one end of the electronic device

4. The testing device of claim 3, wherein the bottom plate defines a rectangular recessed portion near the front end plate, the first latching member further comprises a sliding plate slidably received in the recessed portion, the positioning hook is perpendicularly formed at one end of the sliding plate.

5. The testing device of claim 4, wherein the recessed portion forms a pair of flanges at two opposite sides thereof, a inside of each flange defines a first latching hole and a second latching hole, each side of the sliding plate forms a first latch and a second latch capable of slidably engaging in the first latching hole and the second latching hole.

6. The testing device of claim 4, wherein a pair of sliding slots is defined in the recessed portion, a pair of elastic sliding hooks extends from the sliding plate for slidably extending through the sliding slots, respectively.

7. The testing device of claim 3, wherein an operating notch is defined in the positioning hook.

8. The testing device of claim 3, wherein the mounting tray comprises a bottom wall, a pair of sidewalls perpendicularly formed at two opposite ends of the bottom wall a receiving space is bounded by the bottom wall and the sidewalls to slidably receive the second latch member.

9. The testing device of claim 8, wherein a resilient latch extends forward from an outside surface of each sidewall of the mounting tray, a pair of latching posts is formed at an outside surface of the rear end plate of the bracket to engage with the latches of the mounting tray.

10. The testing device of claim 8, wherein the second latching device comprises a positioning member and a sliding member attached to the positioning member, a connector is sandwiched between the positioning member and the sliding member to electronically couple with the electronic device.

11. The testing device of claim 10, wherein a guiding bar is perpendicularly formed at an inner wall of each sidewall of the mounting tray, a resilient extension member extends forward from two opposite ends of the sliding member, a hook is formed at a bottom portion of each extension member to slidably engage with bottoms of the guiding bar.

12. The testing device of claim 10, wherein a first latching hole and a second latching hole are defined in an inner surface of each guiding bar, a latch is formed at a front portion of each extension member to engage in the first latching hole and the second latching hole of the corresponding guiding bar.

13. The testing device of claim 10, wherein an elastic locating hook extends upward from a front portion of the bottom wall of the mounting tray, a slot is defined in a bottom of the positioning member to engage with the locating hook.

14. The testing device of claim 13, wherein an operation notch is defined in a middle portion of the sliding member.
